(19) United States
(12) Patent Application Publication
(10) Pub. No.: US 2017/0207191 A1
(43) Pub. Date: Jul. 20, 2017

(54) BONDING SYSTEM AND ASSOCIATED APPARATUS AND METHOD

(71) Applicant: TAIWAN SEMICONDUCTOR MANUFACTURING COMPANY LTD., HSINCHU (TW)

(72) Inventors: XIN-HUA HUANG, CHANGHUA COUNTY (TW); PING-YIN LIU, TAIPEI COUNTY (TW); CHIN-WEI LIANG, HSINCHU COUNTY (TW); YEONG-JYH LIN, NANTOU COUNTY (TW); KUAN-LIANG LIU, PINGTUNG COUNTY (TW); CHIA-SHIUNG TSAI, HSIN-CHU (TW)

(21) Appl. No.: 14/996,907

(22) Filed: Jan. 15, 2016

(51) Int. Cl. H01L 23/00; B23K 1/00; B23K 1/20; H01L 21/67

(52) U.S. Cl. CPC H01L 24/75; H01L 21/67207; H01L 21/67028; B23K 1/0016; B23K 1/206; H01L 2224/7525; H01L 2224/7598

(57) ABSTRACT

A bonding system includes: a storage apparatus, including a chamber, wherein the chamber is configured to accommodate a first semiconductor wafer and a second semiconductor wafer transferred from a load port, and a gas is provided to the chamber to purge oxygen out of the chamber; a surface treatment station, configured to perform a surface activation upon the first and second semiconductor wafers transferred from the storage apparatus; a cleaning station, configured to remove undesirable substances from surfaces of the first and second semiconductor wafers transferred from the surface treatment station; and a pre-bonding station, configured to bond the first and second semiconductor wafers together to produce a bonded first and second semiconductor wafer pair, wherein the first and second semiconductor wafers are transferred from the cleaning station. An associated apparatus and method are also disclosed.

### BACKGROUND

In the manufacturing of semiconductor wafers, manufacturing equipment include many apparatuses for performing the various processes. Each of the apparatuses has a corresponding operation environment, e.g. oxygen-rich, oxygen-poor, oxygen-free, and high vacuum environments. If there is deviation of the operation environment, some undesired defect would form accordingly. For example, in a thin film process, particles caused by unexpected oxidation may substantially damage the yield of semiconductor wafers. Therefore, a well controlled working environment is needed to ensure delivery of high quality products on a consistent basis.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a hybrid bonding system for coupling two or more semiconductor wafers together in accordance with an embodiment of the present disclosure;

FIGS. 2A-2H are diagrams illustrating various stages of an operation performed in the hybrid bonding system in accordance with an embodiment of the present disclosure;

FIG. 3 is a cross-sectional view of the storage apparatus in accordance with an exemplary embodiment of the present disclosure; and

FIGS. 4A to 4C are various stages of purging gas into a storage apparatus in accordance with some embodiments of the disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

When performing a bonding operation, e.g., a hybrid bonding operation, conductive pads have been employed to provide the electrical contact between semiconductor wafers. However, one of the most significant factors that can impact the strength of the electrical connection of conductive pads is oxidation of the conductive pads when exposed to an oxygen-containing environment. Typically, the longer the exposure, the more oxide would be formed. Since semiconductor wafers are typically mass-produced, delays in the manufacturing process often leave wafers “in queue,” awaiting the next step of the manufacturing process, and a queue time (Q-time) of several hours to several days is common.

The concept of the present disclosure is to provide a hybrid bonding system having an inert gas-containing storage apparatus with positive pressure. The storage apparatus is for temporarily storing of semiconductor wafers, and the inert gas prevents or relaxes the formation of an oxide material on the top surfaces of the conductive pads. In some embodiments of the disclosure, for example, the conductive pads are comprised of copper (Cu) or copper alloys, and the inert gas prevents or relaxes the formation of copper oxide, e.g., CuO, Cu₂O, and CuO₂, on the top surfaces of the conductive pads. The oxide material on the top surfaces of the conductive pads may lead to degradation of electrical performance by increasing contact resistances and facilitating electromigration, thus causing device yield and reliability concerns. Through the disclosed hybrid bonding system, contamination and oxidation of copper may be reduced or prevented. As such, an entire queue time in the hybrid bonding procedure can be prolonged.

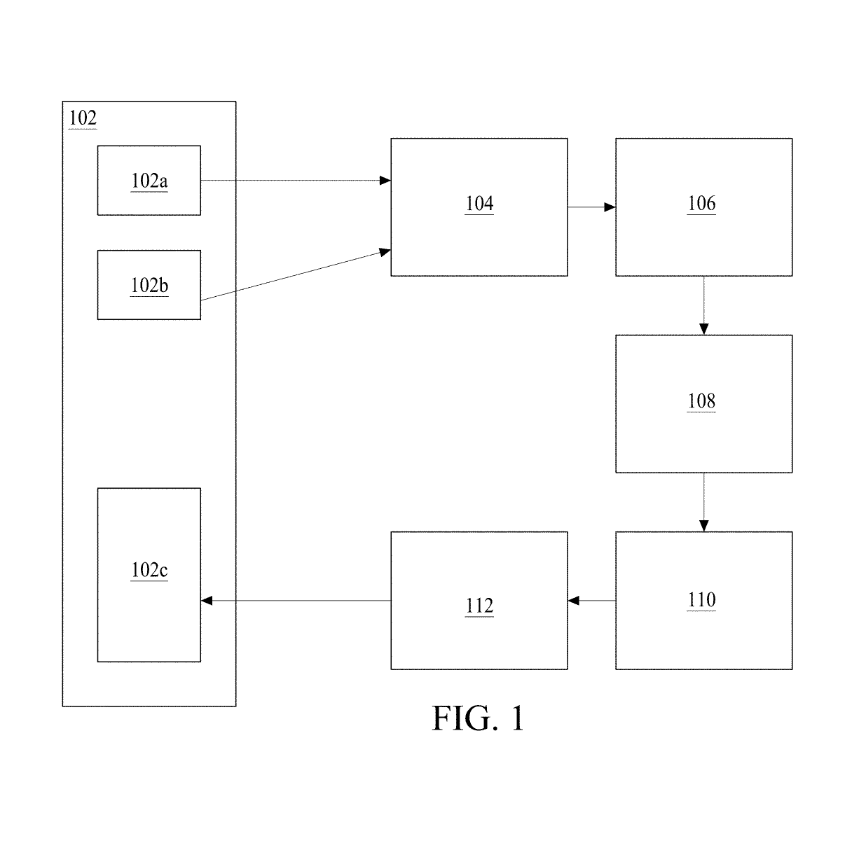

FIG. 1 is a diagram illustrating a hybrid bonding system for coupling two or more semiconductor wafers together in accordance with an embodiment of the present disclosure. For example, the semiconductor wafer may include a semiconductor substrate comprised of silicon or other semiconductor materials and may be covered by an insulating layer. For example, the semiconductor wafer may include silicon oxide over single-crystal silicon. Compound semiconductors, GaAs, InP, Si/Ge, or SiC, as examples, may be used in place of silicon. In some embodiments, the semiconductor wafer may include a silicon-on-insulator (SOI) or a germanium-on-insulator (GOI) substrate, as examples.

The semiconductor wafer may include a device region formed proximate a top surface of the workpiece. The device region includes active components or circuits, such as conductive features, implantation regions, resistors, capacitors and other semiconductor elements, e.g., transistors, diodes, etc. The device region is formed over the semiconductor wafer in a front-end-of-line (FEOL) process in some embodiments, for example. The semiconductor wafer may also include through-substrate vias (TSVs) including a conductive material that provides connections from a bottom side to a top side of the workpiece.

A metallization structure may be formed over the semiconductor wafer, e.g., over the device region of the semiconductor wafer. The metallization structure is formed over the semiconductor wafer in a back-end-of-line (BEOL) process in some embodiments, for example. The metallization structure includes conductive features, such as conductive lines, vias, and conductive pads formed in an insulating material. The conductive pads include contact pads or bond pads formed on a top surface of the semiconductor wafer, as examples. Some of the vias couple conductive pads to conductive lines in the metallization structure, and other vias couple contact pads to the device region of the semiconductor wafer. Vias may also connect with conductive lines in different metallization layers. The conductive features may include conductive materials typically used in BEOL processes, such as Cu, Al, W, Ti, TiN, Ta, TaN, or multiple layers or combinations thereof. In accordance with an embodiment, the conductive pads disposed proximate a top surface of the metallization structure include Cu or a copper alloy, for example. The metallization structure shown is merely for illustrative purposes: the metallization structure may include other configurations and may include one or more conductive lines and via layers, for example. Some semiconductor wafers may have three conductive lines and via layers, or four or more conductive lines and via layers, as other examples. The semiconductor wafer includes dies that may each be shaped in a square or rectangular pattern in a top view.

Referring back to FIG. 1, the hybrid bonding system includes a load port 102, a storage apparatus 104, a surface treatment station 106, a cleaning station 108, an alignment and pre-bonding station 110, and an annealing station 112. The hybrid bonding system may be located in a controlled environment, for example, filled with clean air or nitrogen. Alternatively, the hybrid bonding system is located in open air.

In this embodiment, the load port 102 is a container used to portably store a plurality of semiconductor wafers between processing steps. The load port 102 may be placed at an interface of the hybrid bonding system and is generally provided with a movable door configured to automatically open or close. Depending on a number of factors, such as the size of a production run, cycle time and so on, a plurality of semiconductor wafers may be contained in the load port 102 for a substantial length of time between processing steps. In some embodiments, the semiconductor wafers are held spaced apart in a stack and supported by slots in the load port 102.

The load port 102 includes a first front-opening unified pod (FOUP) 102a, a second FOUP 102b, and a third FOUP 102c. The first FOUP 102a is configured to receive and accommodate at least one first semiconductor wafer; the second FOUP 102b is configured to receive and accommodate at least one second semiconductor wafer, wherein the first semiconductor wafer and the second semiconductor wafer are bonded together through the apparatus 104 and stations 106-112 of the hybrid bonding system of FIG. 1. The bonded semiconductor wafer may be stored back to the load port 102 and contained in the third FOUP 102c. The first, second and bonded semiconductor wafers may be transferred by robotic arms.

The storage apparatus 104 is a container or chamber configured to temporarily accommodate the first and second semiconductor wafers required to be bonded together through the hybrid bonding operations performed later on. The storage apparatus 104 is an inert gas-containing storage apparatus. In this embodiment, the storage apparatus 104 is configured to have a positive pressure. However, this is not a limitation of the present disclosure. As mentioned before in this disclosure, the inert gas prevents or relaxes the formation of an oxide material on the top surfaces of the conductive pads.

The surface treatment station 106 is configured to perform a surface treatment, i.e., an activation operation, including activating the top surfaces of the semiconductor wafers. In some embodiments, the surface treatment includes a plasma treatment. The plasma treatment may be performed in a vacuum environment (a vacuum chamber), for example, which is a part of the surface treatment station. The process gas used for generating the plasma may be a hydrogen-containing gas, which includes a first combined gas of hydrogen (H₂) and argon (Ar), a second combined gas of H₂ and nitrogen (N₂), or a third combined gas of H₂ and helium (He). Through the treatment, the number of OH groups at the surface dielectric layer is increased, which is beneficial for forming strong fusion bonds. The plasma treatment may also be performed using pure or substantially pure H₂, Ar, or N₂ as the process gas, which treats the surfaces of metal pads and surface dielectric layer through reduction and/or bombardment.

The plasma used in the treatment may be low-power plasma, for example, with the power for generating the plasma being between about 10 Watts and about 2,000 Watts. However, this is not a limitation of the present disclosure. In some embodiment, the plasma is at a power density of less than about 1,000 Watts. In the surface treatment, the exposed surfaces of dielectric materials are activated. The activation operation may also clean the top surface of the semiconductor wafers in some embodiments. For example, if any oxide material is left remaining on the top surface of the contact pads, a portion or all of the remaining oxide material may be removed during the activation operation.

The cleaning station 108 is configured to perform a cleaning operation to remove metal oxides, chemicals, particles, or other undesirable substances on the semiconductor wafers. The cleaning operation may include a metal oxide removal, exposure to deionized (DI) H₂O, exposure to NH₄OH, exposure to diluted hydrofluoric acid (DHF) (e.g., at a concentration of less than about 1% HF acid), exposure to other acids, a cleaning process with a brush, a mega-sonic procedure, a spin process, exposure to an infrared (IR) lamp, or a combination thereof, as examples, although alternatively, the cleaning process may comprise other types of cleaning processes. The cleaning station 108 may include a chamber, which may be sealed to confine the chemical vapor. Chemical vapor is evaporated from the chemicals used in the cleaning processes that are performed inside the chamber.

The cleaning operation enhances a density of a hydroxy group disposed on top surfaces of the semiconductor wafers in some embodiments, e.g., on the top surface of the conductive pads. Enhancing the density of the hydroxy group on the conductive pads advantageously increases bonding strength and reduces the anneal temperature required for the hybrid bonding process, for example.

The alignment and pre-bonding station 110 is configured to perform a pre-bonding operation upon the first and second semiconductor wafers. The bonding of the second semiconductor wafer to the first semiconductor wafer is achieved by aligning the conductive pads on the second semiconductor wafer with the conductive pads on the first semiconductor wafer. The alignment of the first and second semiconductor wafers may be achieved using optical sensing, as an example. Top surfaces of the insulating material of the second semiconductor wafer are also aligned with top surfaces of the insulating material of the first semiconductor wafer.

After the alignment, the first and second semiconductor wafers are hybrid bonded together by applying pressure and heat. The pressure applied may include a pressure of less than about 30 MPa, and the heat applied may include an anneal process at a temperature of about 100 to 500° C., as examples, although alternatively, other amounts of pressure and heat may be used for the hybrid bonding process. The hybrid bonding process may be performed in an N₂ environment, an Ar environment, a He environment, an inert-mixing gas environment, combinations thereof, or other types of environments.

The bonded first and second semiconductor wafers in combination are referred to as a bonded semiconductor wafer pair hereinafter. The bonded semiconductor wafer pair is annealed in the annealing station 112 and is annealed at a temperature between about 300° C. and about 400° C., for example. However, this is not a limitation of the present disclosure. In some embodiments, the bonded semiconductor wafer pair is annealed at a temperature between about 100° C. and about 500° C. The annealing may be performed for a period of time between about 1 hour and 2 hours in some exemplary embodiments. When the temperature rises, the OH bonds in oxide layers break to form strong Si—O—Si bonds, and hence, the first and second semiconductor wafers are bonded to each other through fusion bonds. In addition, during the annealing, the copper in metal pads diffuse to each other so that metal-to-metal bonds are also formed. Hence, the resulting bonds between the first and second semiconductor wafers are hybrid bonds.

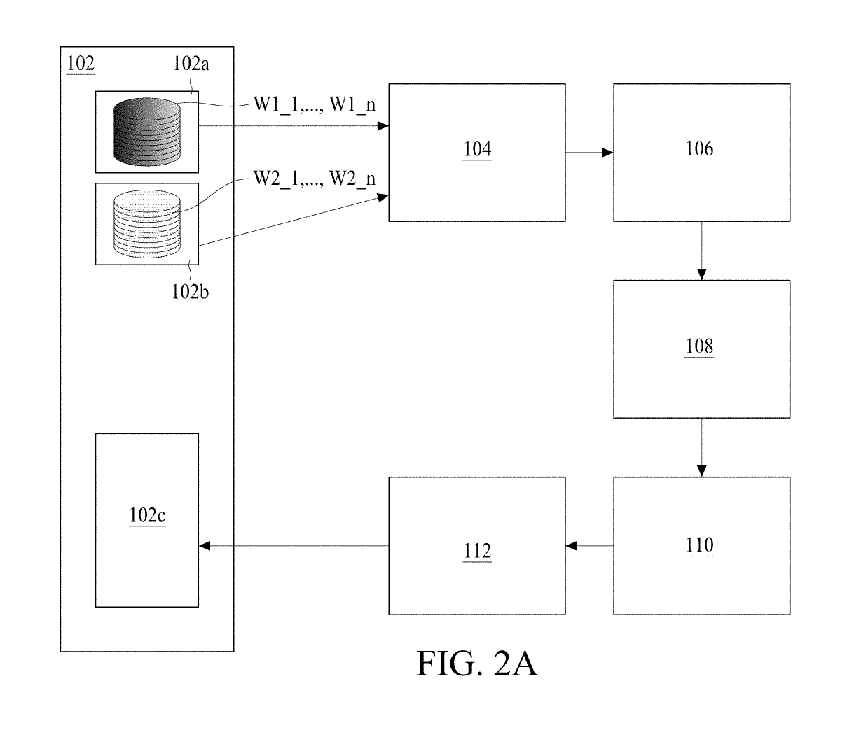

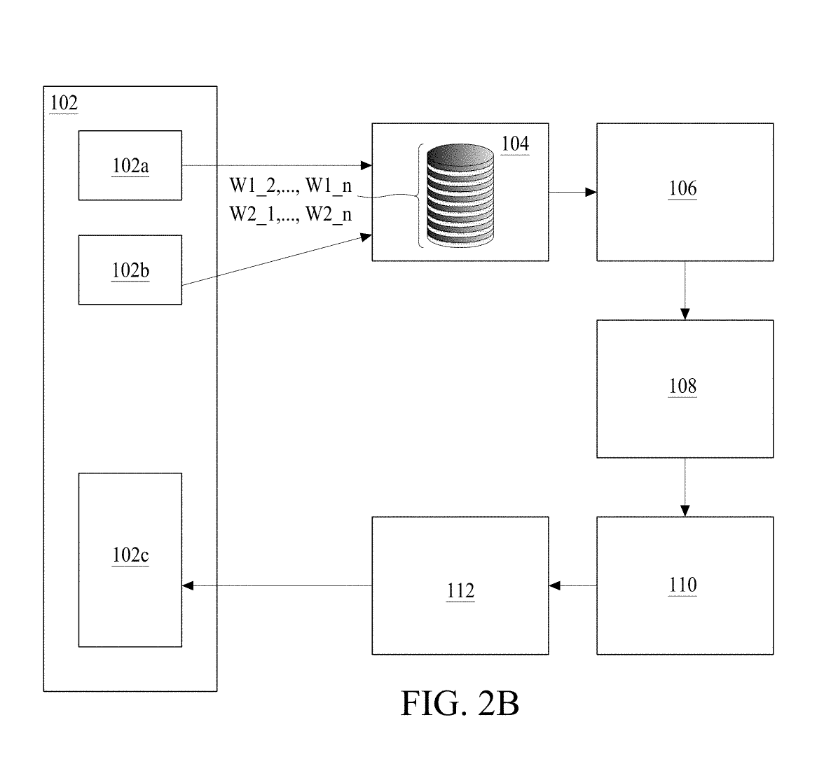

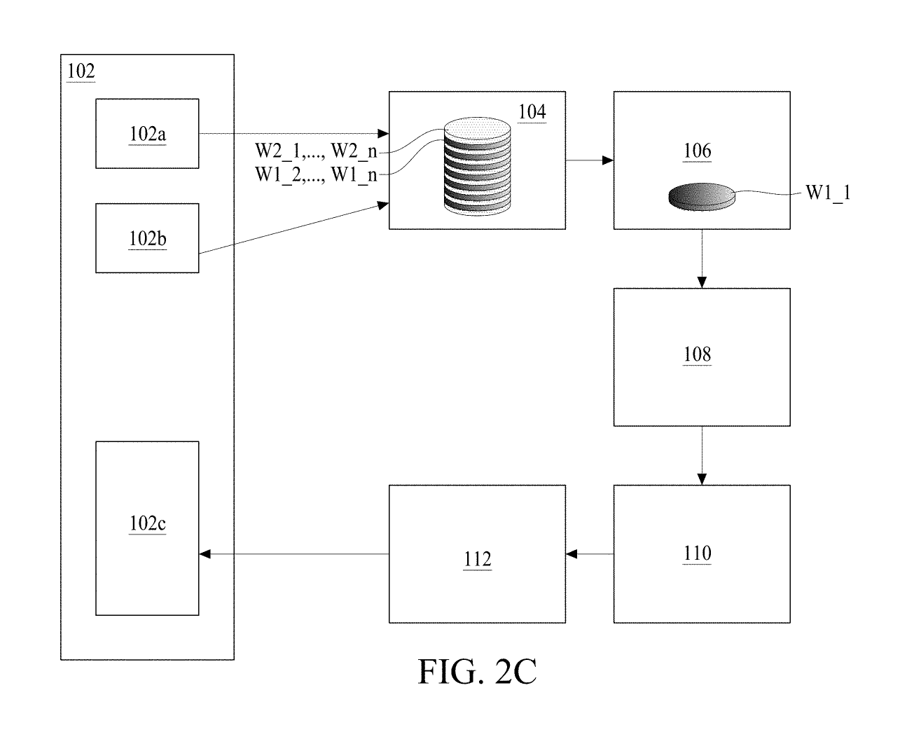

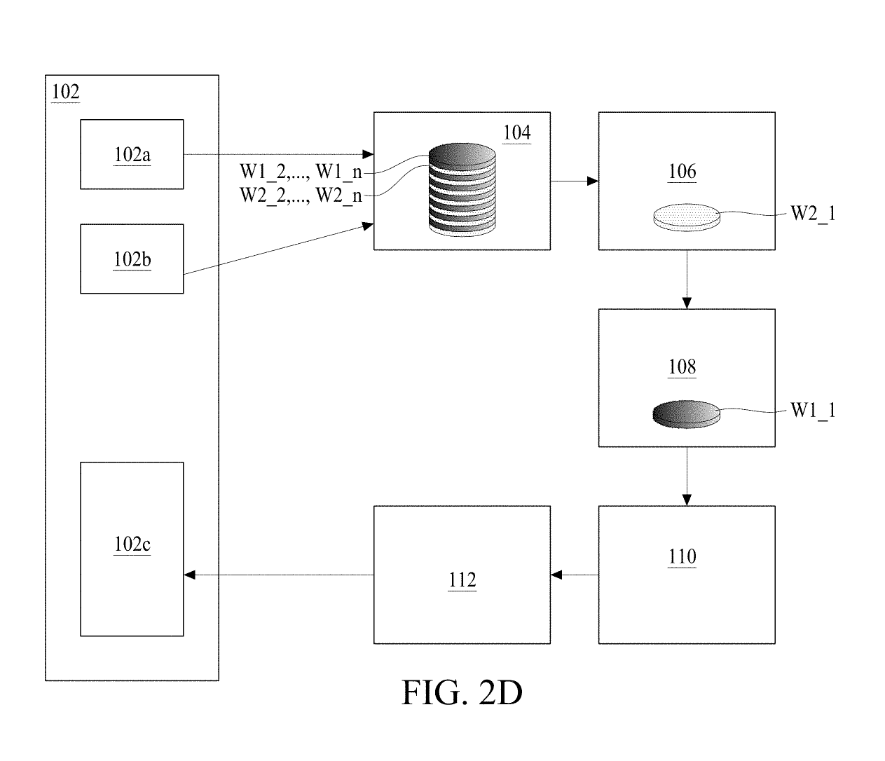

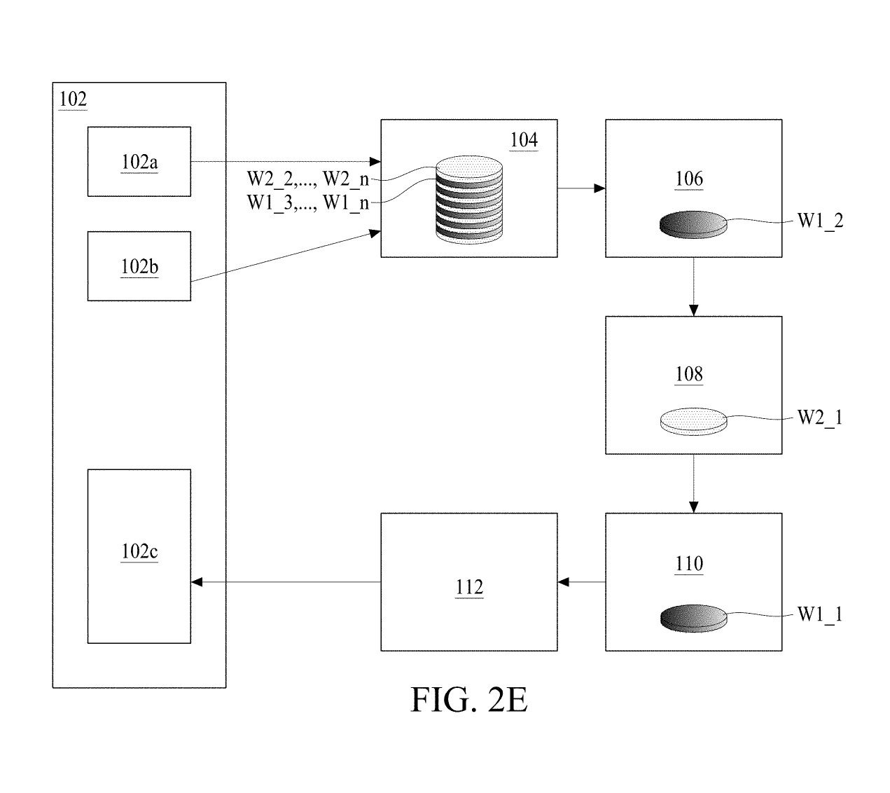

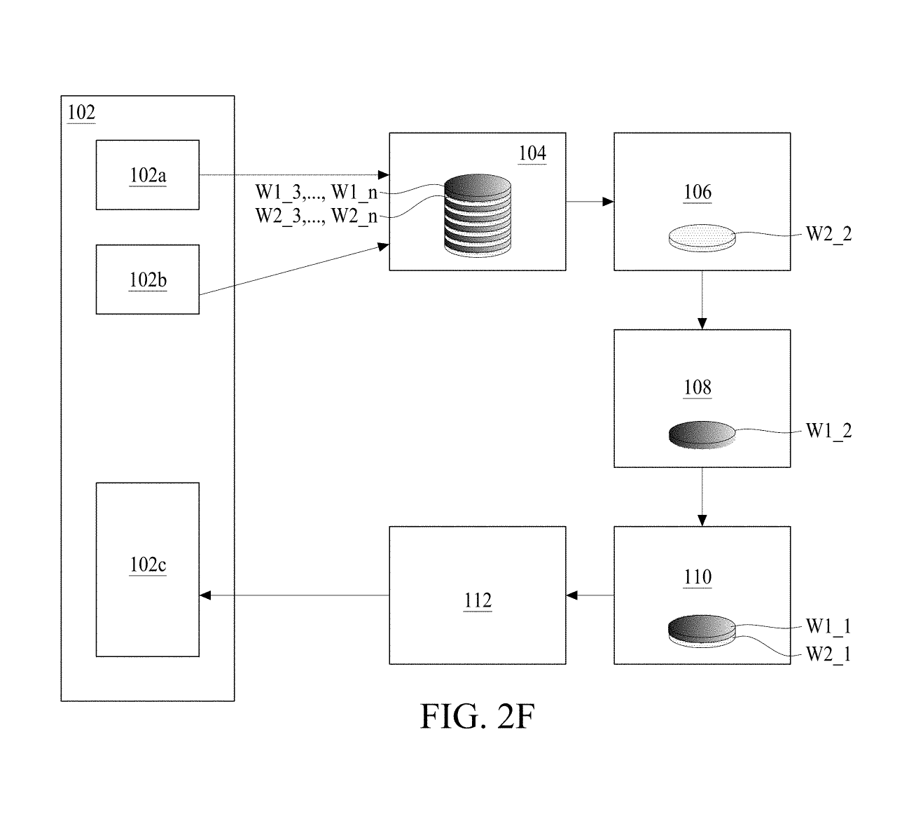

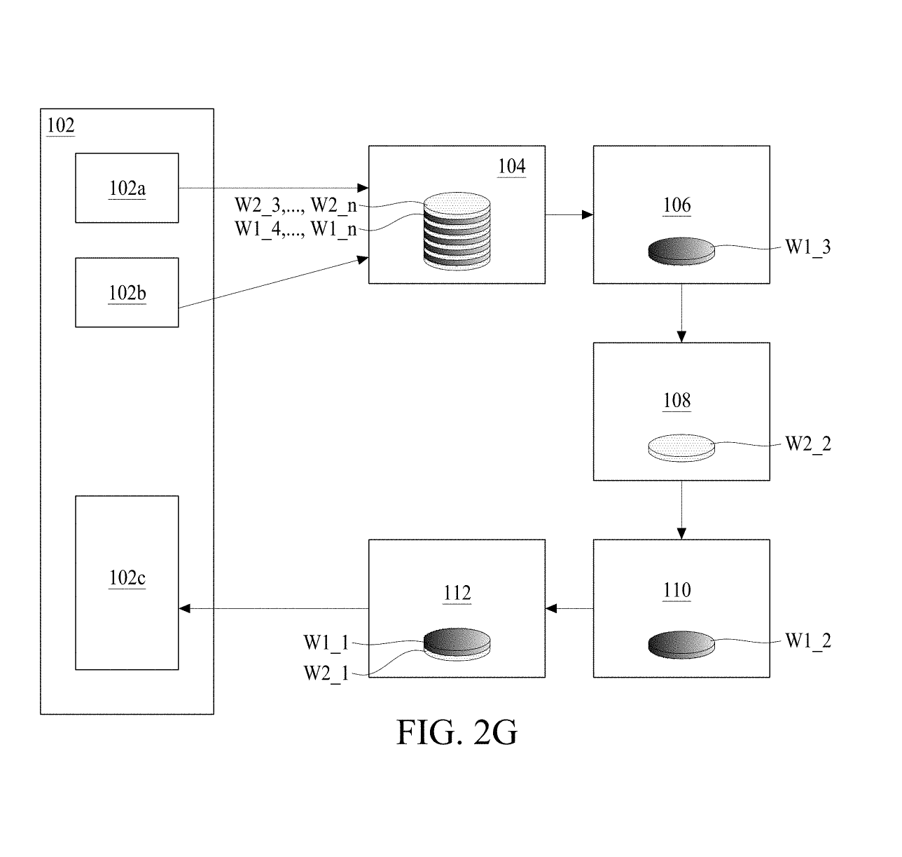

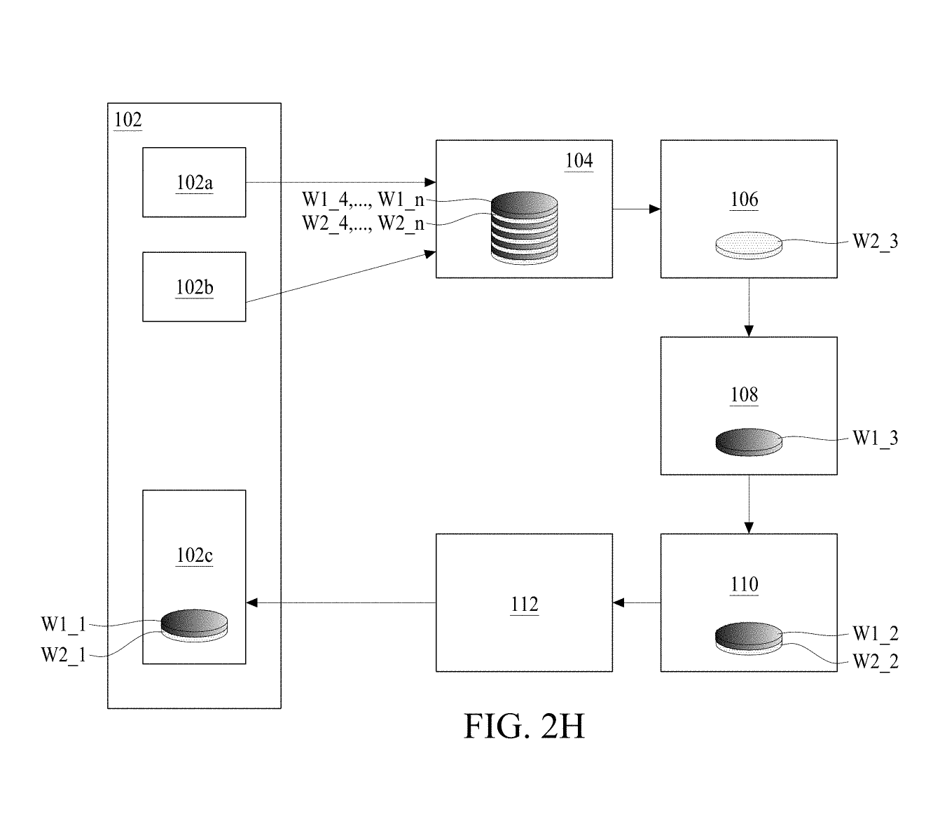

FIGS. 2A-2H are diagrams illustrating various stages of an operation of the hybrid bonding system in accordance with an embodiment of the present disclosure. In FIG. 2A, a plurality of first semiconductor wafers W1_1, W1_2, . . . , and W1_n and a plurality of second semiconductor wafers W2_1, W2_2, . . . , and W2_n are stored in the first FOUP 102a and the second FOUP 102b of the load port 102, respectively, where n is a positive integer. The first and second semiconductor wafers W1_1, . . . , W2_n are stored in the load port 102 and wait for the subsequent hybrid bonding operation performed by the apparatus 104 and stations 106-112.

In FIG. 2B, the first and second semiconductor wafers W1_1, . . . , W2_n are transferred to the storage apparatus 104. In this embodiment, the first and second semiconductor wafers W1_1, . . . , W2_n may be transferred to the storage apparatus 104 in an interleaved way. Therefore, the first and second semiconductor wafers W1_1, . . . , W2_n interleaved together can be placed in the storage apparatus 104 in order to facilitate the subsequent operating procedures. However, this is not a limitation of the present disclosure. In some embodiments, the first and second semiconductor wafers W1_1, . . . , W2_n may not be transferred to the storage apparatus 104 in an interleaved way.

As shown in FIG. 2C, one of the first semiconductor wafers W1_1 is transferred to the surface treatment station 106 for the surface treatment/activation operation. In FIG. 2D, the first semiconductor wafer W1_1 is then transferred to the cleaning station 108 to remove metal oxides, chemicals, particles, or other undesirable substances from the surfaces of the first semiconductor wafer, and one of the second semiconductor wafers W2_1 is transferred to the surface treatment station 106.

In FIGS. 2E and 2F, the first semiconductor wafer W1_1 and the second semiconductor wafer W2_1 arrive at the pre-bonding station 110 one after another. The pre-bonding is then performed to bond the first and second semiconductor wafers W1_1 and W2_1 together. The semiconductor wafers of the stations 106 and 108 are transferred to the next station, and a following second semiconductor wafer is fed into the surface treatment station 106 in FIG. 2F. After the pre-bonding, the first and second semiconductor wafers W1_1 and W2_1 are bonded to each other. The bonded semiconductor wafer pair may then be unloaded from the pre-bonding station 110 and transferred into the annealing station 112 as shown in FIG. 2G. The bonding strength is then enhanced through a thermal annealing, which is held in the thermal annealing station 112. Referring to FIG. 2H, the bonded semiconductor wafer pair being annealed may be moved back to the third FOUP 102c of the load port 102.

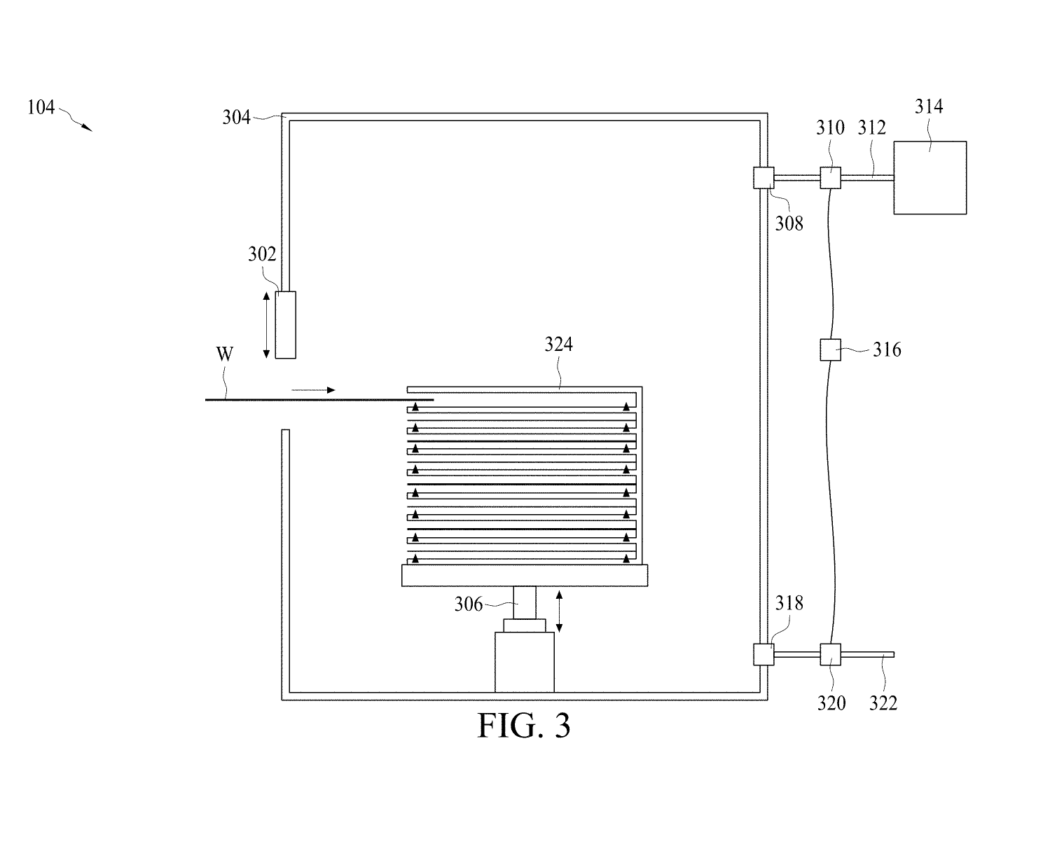

FIG. 3 is a cross-sectional view of the storage apparatus 104 in accordance with an exemplary embodiment of the present disclosure. The storage apparatus 104 includes a chamber 304. The chamber 304 includes a movable door 302, which can be opened to allow a semiconductor wafer W to be transported into and out of the chamber 304. The semiconductor wafer W may be placed in a semiconductor wafer carrier 324, which possesses a plurality of slots for accommodating a plurality of semiconductor wafers. A retractable wafer support 306 connected to the semiconductor wafer carrier 324 may be used to adjust a height of the semiconductor wafer carrier 324 to a level suitable for placing the semiconductor wafer W to an empty slot of the semiconductor wafer carrier 324. However, this is not a limitation of the present disclosure.

In some embodiments, in accordance with the present disclosure, the storage apparatus 104 has a nozzle 308 and a venting hole 318, or vent port, on a sidewall of the chamber 304. In some embodiments, the nozzle 308 and the venting hole 318 may be disposed on a bottom or top of the chamber 304. The nozzle 308 is configured to provide a gas output from a gas source 314 via a gas line 312 into the chamber 304. Moreover, the venting hole 318 is configured to lead gas out of the chamber 304.

In some embodiments, the gas provided into the chamber 304 is an inert gas. Inert gas serves to lower the possibility of undesired defects developed on the semiconductor wafer W accommodated in the chamber 304. In certain embodiments, the gas provided is nitrogen. Before the gas is provided by the nozzle 308 into the chamber 304, the oxygen concentration within the chamber 304 is at a certain level. After the gas is provided by the nozzle 308, the air and/or gas in the chamber 304 is purged or replaced by the gas provided or flowed into the chamber 304, and a substantially oxygen-free environment is generated in the chamber 304. The term “substantially oxygen-free environment” used in the present disclosure is to define an environment having an oxygen concentration below about 5.0% to about 10.0%. In certain embodiments, the term “substantially oxygen-free environment” used in the present disclosure is to define an environment having an oxygen concentration below about 3.0%. In some embodiments, a term “oxygen-poor” is another alternative definition to replace “substantially oxygen-free environment” in the present disclosure.

In some embodiments, in accordance with the present disclosure, the nozzle 308 is connected to the gas source 314 through a gas line 312. The gas source 314 is within the storage apparatus 104. In certain embodiments, the gas source 314 is located outside of or external to the storage apparatus 104 and configured to be connected to the nozzle 308 through the gas line 312.

In some embodiments in accordance with the present disclosure, the gas source 314 is configured to provide gas through the nozzle 308 and into the chamber 304 continuously. In certain embodiments, the storage apparatus 104 includes a control valve 310 for manipulating the gas provided into the chamber 304. For example, the control valve 310 is configured to control the flow speed or the amount of the gas provided.

In some embodiments, in accordance with the present disclosure, the storage apparatus 104 includes a controller 316 connected to the control valve 310. The controller 316 is configured to control the control valve 310 so as to manipulate the output of the nozzle 308. For example, the controller 316 is programmed to allow gas output for a predetermined period whenever the semiconductor wafer W is received through the door 302. In certain embodiments, the controller 316 is manually adjusted so as to manipulate different types of gas output from the nozzle 308.

In some embodiments, in accordance with the present disclosure, the storage apparatus 104 includes a sensor 320 connected to the controller 316. The sensor 320 is disposed proximal to the venting hole 318 so as to monitor an ambient condition within the chamber 304. In some embodiments, the sensor 320 is connected to an exhaust pipe 322 connecting the venting hole 318 to lead the gas purged out of the chamber 304. Accordingly, the sensor 320 is configured to detect the ambient condition of the gas purged out of the chamber 304. In certain embodiments, the sensor 320 is connected to a detection pipe extending into the inner space of the chamber 304. In certain embodiments, the sensor 320 is disposed proximal to the nozzle 308 so as to detect the ambient condition of the gas outputted by the nozzle 308.

In some embodiments, in accordance with the present disclosure, the controller 316 receives the ambient condition detected by the sensor 320. Then, the controller 316 adjusts the control valve 310 based on the ambient condition so as to manipulate the output provided by the nozzle 308. In other words, after receiving the ambient condition from the sensor 320, the controller 316 compares the ambient condition with predetermined values stored in a memory. When an ambient condition reaches, passes, or decreases below a certain value, the controller 316 is configured to react and adjust the control valve 310 so as to manipulate the output of the nozzle 308.

In some embodiments, in accordance with the present disclosure, the sensor 320 includes an oxygen sensor proximal to the venting hole 318. In some embodiments, the sensor 320 is located downstream of the venting hole 318 in the direction of the gas flow through the venting hole. The oxygen sensor is configured to monitor an oxygen concentration in the chamber 304. The oxygen sensor may be a chemical oxygen sensor or an optical oxygen sensor. In certain embodiments, when an oxygen concentration in the chamber 304 is above about 2%, the controller 316 is configured to adjust the control valve 310 to provide gas output so as to purge the chamber 304.

In some embodiments, in accordance with the present disclosure, the sensor 320 includes a pressure sensor. The pressure sensor is configured to monitor a pressure level in the chamber 304 or a pressure difference between the inner space of the chamber 304 and the outer atmosphere. In this embodiment, a pressure difference between the inner space and the atmosphere outside the chamber 304 is a positive pressure value.

In some embodiments in accordance with the present disclosure, the nozzle 308 includes a diffuser configured to provide a more uniform gas output into the chamber 304. The diffuser also provides another function of adjusting flow direction, speed or rate of the gas outputted by the nozzle 308. In some embodiments, in accordance with the present disclosure, the nozzle 308 includes a filter configured to reduce particles or contaminants in the gas output. In certain embodiments, the filter is a chemical filter configured to remove chemical contaminants contained in the gas introduced from the gas source 314. In some embodiments, the filter includes an activated carbon filter. In some embodiments, the filter is disposed upstream of the nozzle 308 in the direction of the gas flow through the nozzle 308.

In some embodiments, in accordance with the present disclosure, the venting hole 318 includes a suction unit configured to vacuum the chamber 304 by providing a suction force to pull gas out of the chamber 304. In certain embodiments, the suction unit is a pump. In some embodiments, the suction unit is a fan.

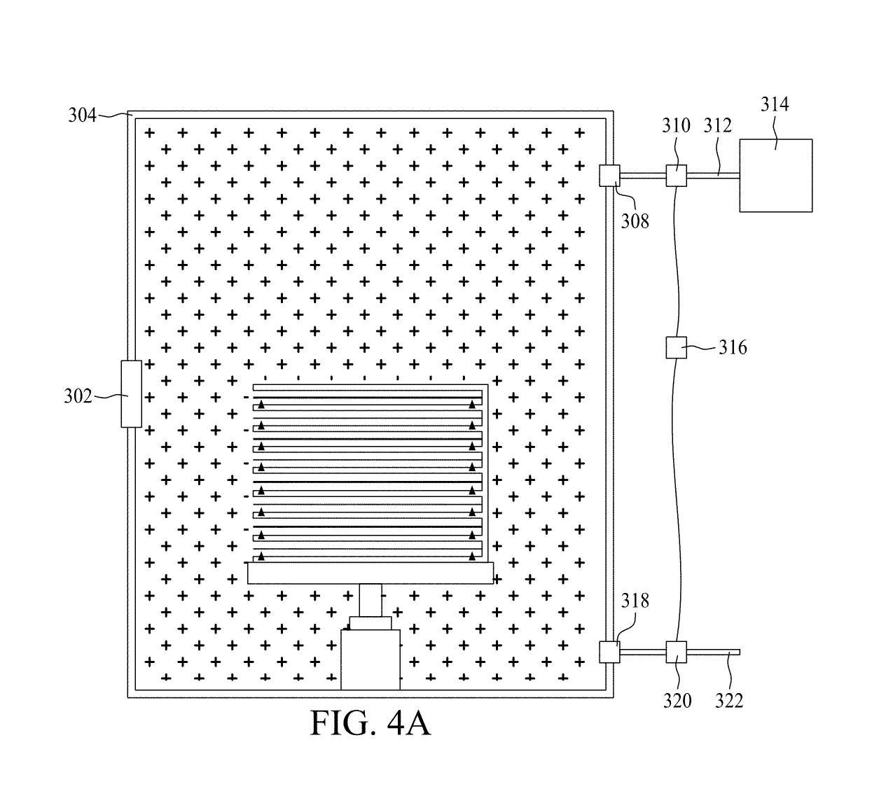

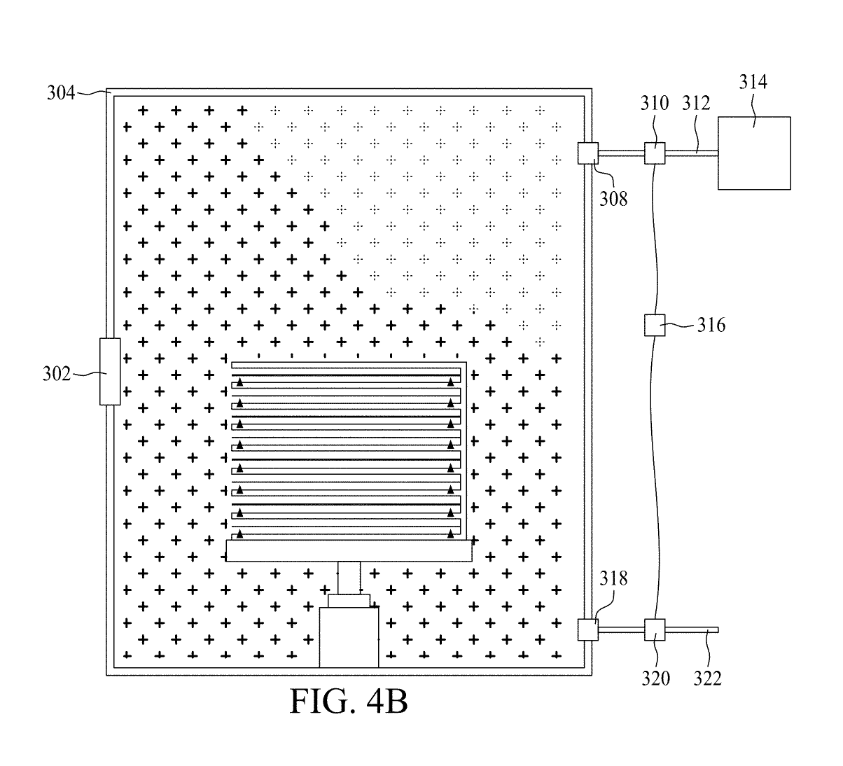

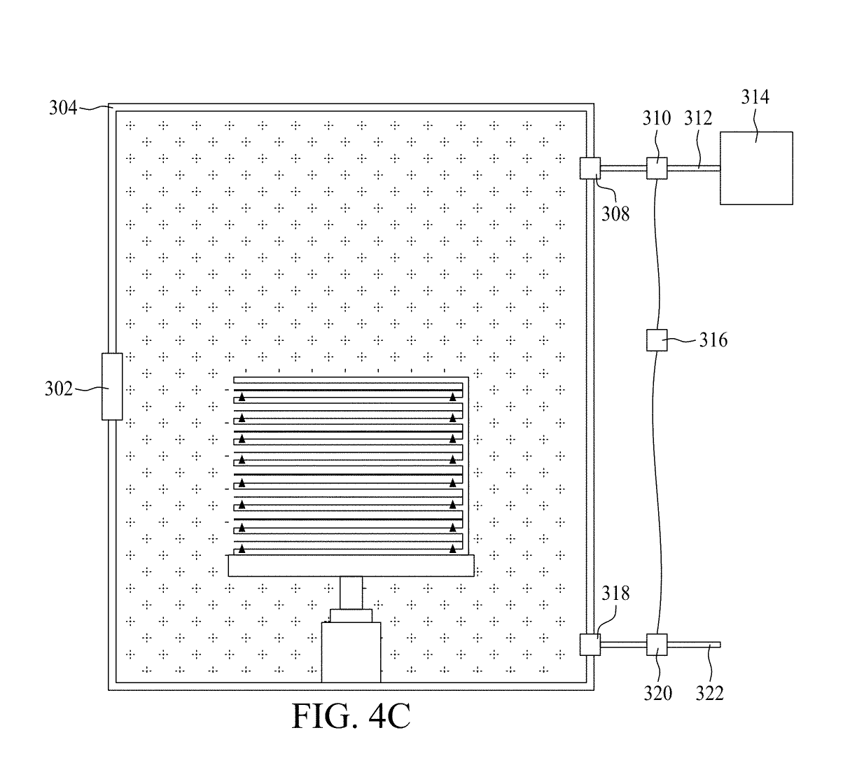

FIGS. 4A to 4C are various stages of purging gas into the storage apparatus 104 in accordance with some embodiments of the disclosure. In FIG. 4A, semiconductor wafers are stored in the chamber 304 and the movable door 302 is closed. Inert gas in the gas source 314 has not been supplied into the chamber 304 yet. In certain embodiments, the sensor 320 detects an ambient condition in the chamber 304 and transmits the ambient condition detected to the controller 316.

In FIG. 4B, the controller 316 adjusts the control valve 310 so as to manipulate the nozzle 308 to provide inert gas into the chamber 304. Due to the inert gas supply, oxygen in the chamber 304 is purged out or removed through the venting hole 318. In some embodiments, the controller 316 is configured to flow or discharge inert gas into the chamber 304 for a predetermined period of time whenever the movable door is recently closed. In certain embodiments, the controller 316 is configured to receive the ambient condition detected by the sensor 320. The controller 316 compares the ambient condition with a predetermined value and determines whether a specific event occurs. For example, the specific event is an oxygen concentration of over 2%. In response to the occurrence of the specific event, the controller 316 adjusts the inert gas provided by the gas source 314 by manipulating the control valve 310.

In FIG. 4C, the inert gas continues to be provided into the chamber 304. Oxygen in the chamber 304 is purged out or removed through the venting hole 318 by the gas provided. The purged gas, which includes oxygen, is led out of the chamber 304 through the exhaust pipe 322. Accordingly, a substantially oxygen-free environment is generated in the chamber 304. In some embodiments, the substantially oxygen-free environment has an oxygen concentration below about 3%. In certain embodiments, the oxygen concentration of the substantially oxygen-free environment is close to about 0.0%.

Some embodiments of the present disclosure provide a bonding system, including: a storage apparatus, including a chamber, wherein the chamber is configured to accommodate a first semiconductor wafer and a second semiconductor wafer transferred from a load port, and a gas is provided to the chamber to purge oxygen out of the chamber; a surface treatment station, configured to perform a surface activation upon the first and second semiconductor wafers transferred from the storage apparatus; a cleaning station, configured to remove undesirable substances from surfaces of the first and second semiconductor wafers transferred from the surface treatment station; and a pre-bonding station, configured to bond the first and second semiconductor wafers together to produce a bonded first and second semiconductor wafer pair, wherein the first and second semiconductor wafers are transferred from the cleaning station.

In some embodiments of the present disclosure, the bonding system further includes an annealing station, configured to perform a thermal annealing upon the bonded first and second semiconductor wafer pair to enhance bonding strength therebetween.

In some embodiments of the present disclosure, the bonded first and second semiconductor wafer pair is transferred back to the load port after the thermal annealing.

In some embodiments of the present disclosure, the bonding system is a hybrid bonding system.

In some embodiments of the present disclosure, the bonding system is located in open air.

In some embodiments of the present disclosure, the gas provided to the chamber of the storage apparatus is nitrogen.

In some embodiments of the present disclosure, the gas provided to the chamber of the storage apparatus is an inert gas.

In some embodiments of the present disclosure, the storage apparatus is further configured to accommodate a plurality of first semiconductor wafers and a plurality of second semiconductor wafers transferred from the load port in an interleaved way.

In some embodiments of the present disclosure, the gas is provided to the chamber of the storage apparatus for a specified time so as to allow the chamber to become substantially oxygen-free.

Some embodiments of the present disclosure provide an apparatus for temporarily storing a semiconductor wafer transferred from a load port before starting a bonding operation, the apparatus including: a chamber, for accommodating a semiconductor wafer, the chamber including: a door, configured to allow the semiconductor wafer to be transported into and out of the chamber; and a nozzle, configured to provide a gas to the chamber; and a gas source, configured to provide gas through the nozzle.

In some embodiments of the present disclosure, the bonding operation is a hybrid bonding operation.

In some embodiments of the present disclosure, the gas provided to the chamber is nitrogen.

In some embodiments of the present disclosure, the gas provided to the chamber is an inert gas.

In some embodiments of the present disclosure, the chamber further comprises a venting hole configured to lead oxygen out of the chamber.

In some embodiments of the present disclosure, the chamber further includes: a semiconductor wafer carrier; and a retractable wafer support, configured to adjust a height of the semiconductor wafer carrier.

In some embodiments of the present disclosure, the apparatus further includes: a control valve, connected between the nozzle and the gas source, wherein the control valve is configured to manipulate the gas provided into the chamber; and a controller, connected to the control valve, wherein the controller is configured to control the control valve.

In some embodiments of the present disclosure, the apparatus further includes a sensor configured to monitor an ambient condition within the chamber.

In some embodiments of the present disclosure, the gas is provided to the chamber for a specified time so as to allow the chamber to become substantially oxygen-free.

Some embodiments of the present disclosure provide a bonding method, including: utilizing a storage apparatus to accommodate a first semiconductor wafer and a second semiconductor wafer transferred from a load port; providing a gas to the storage apparatus to purge oxygen out of the storage apparatus; and transferring the first and second semiconductor wafers to following stations of a bonding system sequentially one after another; wherein the storage apparatus is substantially oxygen-free.

In some embodiments of the present disclosure, the stations of the bonding system include a surface treatment station, a cleaning station, a pre-bonding station and an annealing station.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A bonding system, comprising:
a storage apparatus, including a chamber, wherein the chamber is configured to accommodate a first semiconductor wafer and a second semiconductor wafer transferred from a load port, and a gas is provided to the chamber to purge oxygen out of the chamber;
a surface treatment station, configured to perform a surface activation upon the first and second semiconductor wafers transferred from the storage apparatus;
a cleaning station, configured to remove undesirable substances from surfaces of the first and second semiconductor wafers transferred from the surface treatment station; and
a pre-bonding station, configured to bond the first and second semiconductor wafers together to produce a bonded first and second semiconductor wafer pair, wherein the first and second semiconductor wafers are transferred from the cleaning station.

2. The bonding system of claim 1, further comprising an annealing station, configured to perform a thermal annealing upon the bonded first and second semiconductor wafer pair to enhance bonding strength therebetween.

3. The bonding system of claim 2, wherein the bonded first and second semiconductor wafer pair is transferred back to the load port after the thermal annealing.

4. The bonding system of claim 1, wherein the bonding system is a hybrid bonding system.

5. The bonding system of claim 1, wherein the bonding system is located in open air.

6. The bonding system of claim 1, wherein the gas provided to the chamber of the storage apparatus is an inert gas.

7. The bonding system of claim 6, wherein the gas provided to the chamber of the storage apparatus is nitrogen.

8. The bonding system of claim 1, wherein the storage apparatus is further configured to accommodate a plurality of first semiconductor wafers and a plurality of second semiconductor wafers transferred from the load port in an interleaved way.

9. The bonding system of claim 1, wherein the gas is provided to the chamber of the storage apparatus for a specified time so as to allow the chamber to become substantially oxygen-free.

10. An apparatus for temporarily storing a semiconductor wafer transferred from a load port before starting a bonding operation, the apparatus comprising:
a chamber, for accommodating a semiconductor wafer, the chamber comprising:
a door, configured to allow the semiconductor wafer to be transported into and out of the chamber; and
a nozzle, configured to provide a gas to the chamber; and
a gas source, configured to provide gas through the nozzle.

11. The apparatus of claim 10, wherein the bonding operation is a hybrid bonding operation.

12. The apparatus of claim 10, wherein the gas provided to the chamber is an inert gas.

13. The apparatus of claim 12, wherein the gas provided to the chamber is nitrogen.

14. The apparatus of claim 10, wherein the chamber further comprises a venting hole configured to lead oxygen out of the chamber.

15. The apparatus of claim 10, wherein the chamber further comprises:
a semiconductor wafer carrier; and
a retractable wafer support, configured to adjust a height of the semiconductor wafer carrier.

16. The apparatus of claim 10, further comprising:
a control valve, connected between the nozzle and the gas source, wherein the control valve is configured to manipulate the gas provided into the chamber; and
a controller, connected to the control valve, wherein the controller is configured to control the control valve.

17. The apparatus of claim 14, further comprising a sensor configured to monitor an ambient condition within the chamber.

18. The apparatus of claim 10, wherein the gas is provided to the chamber for a specified time so as to allow the chamber to become substantially oxygen-free.

19. A bonding method, comprising:
utilizing a storage apparatus to accommodate a first semiconductor wafer and a second semiconductor wafer transferred from a load port;
providing a gas to the storage apparatus to purge oxygen out of the storage apparatus; and
transferring the first and second semiconductor wafers to following stations of a bonding system sequentially one after another;
wherein the storage apparatus is substantially oxygen-free.

20. The bonding method of claim 19, wherein the stations of the bonding system comprise a surface treatment station, a cleaning station, a pre-bonding station and an annealing station.
